(19) United States
(12) Patent Application Publication
(10) Pub. No.: US 2013/0256814 A1
(43) Pub. Date: Oct. 3, 2013

(54) PHYSICAL QUANTITY SENSOR AND ELECTRONIC APPARATUS

(71) Applicant: SEIKO EPSON CORPORATION, Tokyo (JP)

(72) Inventor: Satoru TANAKA, Chino (JP)

(73) Assignee: Seiko Epson Corporation, Tokyo (JP)

(21) Appl. No.: 13/853,396

(22) Filed: Mar. 29, 2013

(30) Foreign Application Priority Data
Apr. 2, 2012 (JP) 2012-084155

(51) Int. Cl. B81B 3/00

(52) U.S. Cl. CPC B81B 3/0021
USPC 257/415

(57) ABSTRACT

A physical quantity sensor includes: a movable body displaceable in a direction of a first axis; a fixed electrode portion disposed to face a movable electrode portion; a spring portion as a connection member connecting a fixed portion with the movable body and including a first extending portion extending from the fixed portion along a second axis crossing the direction of the first axis, a turn-around portion connected to the first extending portion, and a second extending portion extending from the turn-around portion along the second axis; and a wall portion extending from the fixed portion and disposed, in plan view, outside the first extending portion and the turn-around portion of the spring portion. The spring portion and the wall portion are electrically connected.

### BACKGROUND

1. Technical Field

The present invention relates to a physical quantity sensor and an electronic apparatus.

2. Related Art

In recent years, physical quantity sensors that detect a physical quantity using, for example, a silicon MEMS (Micro Electro Mechanical Systems) technique have been developed.

The physical quantity sensor includes a functional element having, for example, a fixed electrode fixed to a substrate and a movable body including a movable electrode arranged to face the fixed electrode via a space. The functional element detects a physical quantity such as acceleration based on an electrostatic capacitance between the fixed electrode and the movable electrode. The movable body is connected via a spring portion to the fixed portion fixed to the substrate, so that the movable body is displaceable according to a change in physical quantity.

In the functional element described above, an unnecessary electrostatic force sometimes exerts especially on the spring portion due to another functional element or a routed wiring. Therefore, desired characteristics sometimes cannot be obtained such as the case where the sensitivity is lowered.

For example, JP-A-2007-279056 (Patent Document 1) discloses that a pad is disposed in a peripheral portion arranged at the periphery of a sensor element portion and a voltage is applied to the pad from a control circuit to fix the potential of the peripheral portion. Then, Patent Document 1 discloses that a potential applied to a movable electrode is applied as a potential for fixing the peripheral portion. With this configuration, for example, an electrostatic force is prevented from exerting between the peripheral portion and a beam portion.

However, in the technique disclosed in Patent Document 1, since a dedicated pad for fixing the potential is disposed in the peripheral portion, it is sometimes difficult to achieve a reduction in the size of the physical quantity sensor.

### SUMMARY

An advantage of some aspects of the invention is to provide a physical quantity sensor that can prevent the exertion of an electrostatic force on a spring portion while achieving a reduction in size. Another advantage of some aspects of the invention is to provide an electronic apparatus having the physical quantity sensor.

The invention can be implemented as the following modes or application examples.

### Application Example 1

A physical quantity sensor according to this application example includes: a movable body including a movable electrode portion and displaceable along a first axis; a fixed electrode portion disposed to face the movable electrode portion; a connection member connecting a fixed portion with the movable body and including a first extending portion extending from the fixed portion along a second axis crossing a direction of the first axis, a turn-around portion connected to the first extending portion, and a second extending portion extending from the turn-around portion along the second axis; and a wall portion extending from the fixed portion and disposed, in plan view, outside the first extending portion and the turn-around portion of the connection member, wherein the connection member and the wall portion are electrically connected.

According to the physical quantity sensor, the exertion of an electrostatic force on the connection member due to a member (for example, another functional element or the like) having a potential different from that of the connection member can be prevented by the wall portion.

Further, according to the physical quantity sensor, since the connection member and the wall portion are electrically connected, there is no need to dispose a dedicated connection terminal for fixing the potential of the wall portion. Therefore, a reduction in size can be achieved. In the physical quantity sensor as described above, the exertion of an electrostatic force on the connection member can be prevented while achieving a reduction in size.

It should be noted that, in the descriptions concerning the invention, the term “electrically connected” is used, for example, in such a phrase as “a specific member (hereinafter referred to as “A member”) “electrically connected” to another specific member (hereinafter referred to as “B member”)”. In the descriptions concerning the invention, in the case of such an example, the term “electrically connected” is used to include the case where A member and B member are electrically connected in direct contact with each other and the case where A member and B member are electrically connected via another member.

### Application Example 2

In the physical quantity sensor according to the application example, the wall portion may include a first wall portion disposed along the first extending portion in plan view and a second wall portion disposed along the turn-around portion in plan view.

According to the physical quantity sensor of this configuration, the exertion of an electrostatic force on the connection member can be prevented more reliably.

### Application Example 3

In the physical quantity sensor according to the application example, an end of the movable body to which the connection member is connected may be located on the fixed portion side of an end of the second wall portion in the direction of the first axis.

According to the physical quantity sensor of this configuration, the exertion of an electrostatic force on the connection member can be prevented more reliably.

### Application Example 4

In the physical quantity sensor according to the application example, the physical quantity sensor may further include a wiring electrically connected to the fixed electrode portion, and the wall portion may be disposed between the connection member and the wiring.

According to the physical quantity sensor of this configuration, the exertion of an electrostatic force on the connection member due to the wiring can be prevented by the wall portion.

### Application Example 5

In the physical quantity sensor according to the application example, the movable electrode portion may be arranged next to the connection member.

According to the physical quantity sensor of this configuration, the exertion of an electrostatic force on the connection member due to the fixed electrode portion can be prevented by the movable electrode portion.

### Application Example 6

In the physical quantity sensor according to the application example, the physical quantity sensor may further include a substrate to which the fixed portion and the fixed electrode are fixed, a recess may be disposed in the substrate, the movable body may be arranged above the recess, and the wall portion may be arranged along the outer edge of the recess.

According to the physical quantity sensor of this configuration, the entire rear surface (lower surface) of the wall portion can be fixed (bonded) to the substrate. With this configuration, the contact area between the wall portion and the substrate can be increased, so that the wall portion can be stably fixed. Moreover, for example, there is no need to, in a substrate where a recess is not disposed, separate the movable body from the substrate via a spacer member. Therefore, the number of members can be reduced, so that a reduction in cost, for example, can be achieved.

### Application Example 7

In the physical quantity sensor according to the application example, the fixed portion, the movable body, the connection member, and the wall portion may be integrally disposed.

According to the physical quantity sensor of this configuration, the fixed portion, the movable body, the connection member, and the wall portion can be integrally formed by, for example, processing a silicon substrate. With this configuration, for example, a fine processing technique used in the manufacture of silicon semiconductor devices is applicable, so that a reduction in size can be achieved.

### Application Example 8

An electronic apparatus according to this application example includes the physical quantity sensor according to the application example.

According to the electronic apparatus, the physical quantity sensor that can prevent the exertion of an electrostatic force on the connection member while achieving a reduction in size can be included.

### BRIEF DESCRIPTION OF THE DRAWINGS

The invention will be described with reference to the accompanying drawings, wherein like numbers reference like elements.

FIG. 1 is a plan view schematically showing a physical quantity sensor according to a first embodiment.

FIG. 2 is a cross-sectional view schematically showing the physical quantity sensor according to the first embodiment.

FIG. 3 is a plan view schematically showing a physical quantity sensor according to a first modified example of the first embodiment.

FIG. 4 is a plan view schematically showing a physical quantity sensor according to a second modified example of the first embodiment.

FIG. 5 is a plan view schematically showing a physical quantity sensor according to a second embodiment.

FIG. 6 is a cross-sectional view schematically showing the physical quantity sensor according to the second embodiment.

FIG. 7 explains the operation of a functional element of the physical quantity sensor according to the second embodiment.

FIG. 8 explains the operation of the functional element of the physical quantity sensor according to the second embodiment.

FIG. 9 explains the operation of the functional element of the physical quantity sensor according to the second embodiment.

FIG. 10 explains the operation of the functional element of the physical quantity sensor according to the second embodiment.

FIG. 11 is a perspective view schematically showing an electronic apparatus according to a third embodiment.

FIG. 12 is a perspective view schematically showing an electronic apparatus according to the third embodiment.

FIG. 13 is a perspective view schematically showing an electronic apparatus according to the third embodiment.

### DESCRIPTION OF EXEMPLARY EMBODIMENTS

Hereinafter, preferred embodiments of the invention will be described in detail using the drawings. The embodiments described below do not unduly limit the contents of the invention set forth in the appended claims. Moreover, not all of configurations described below are indispensable constituent features of the invention.

### 1. First Embodiment

### 1.1. Physical Quantity Sensor

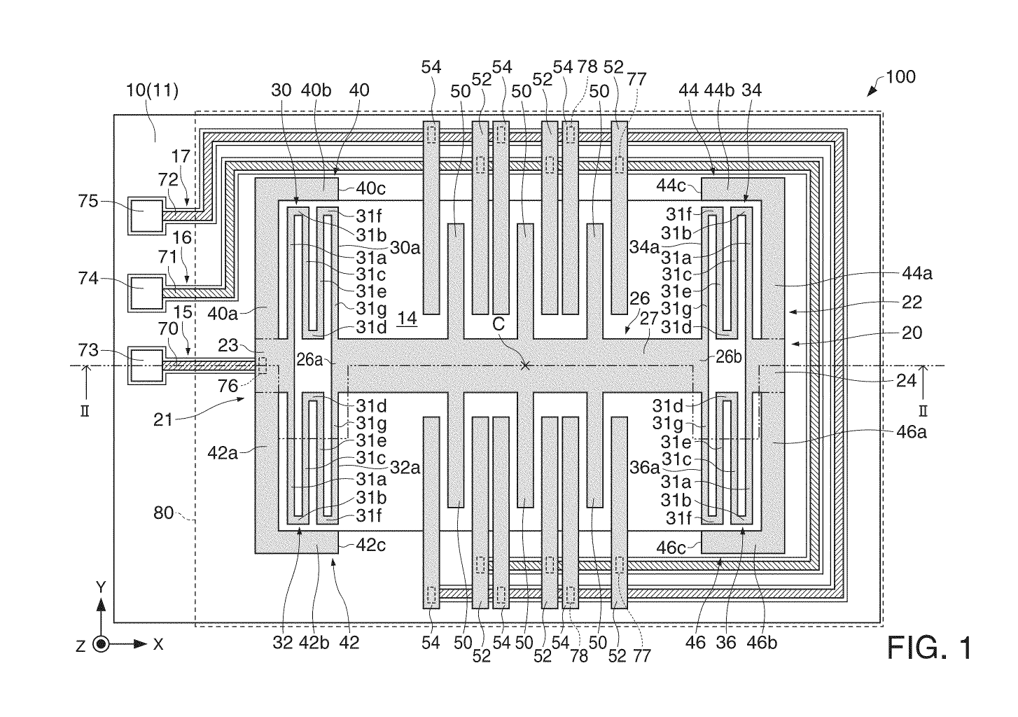

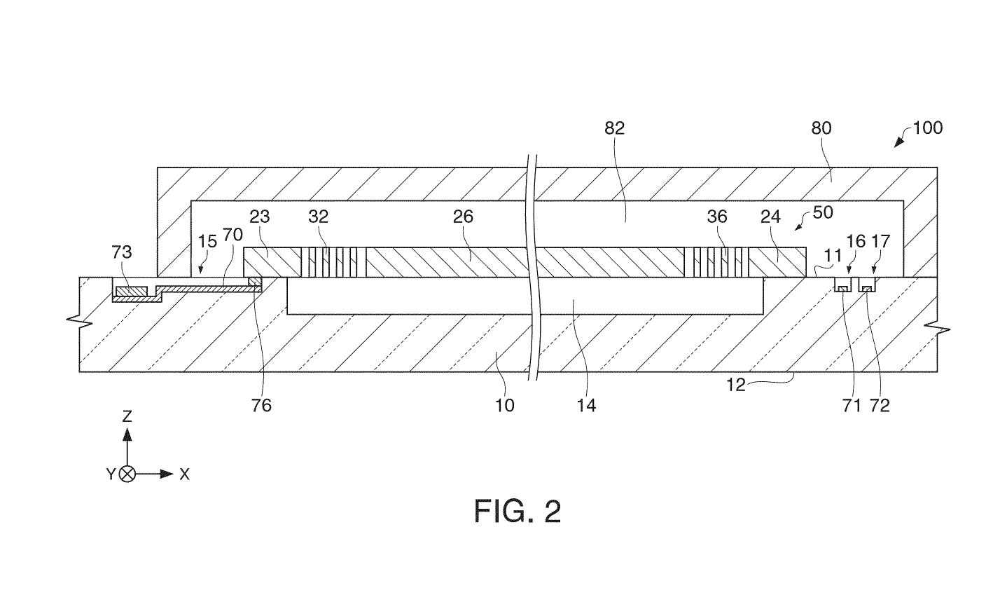

First, a physical quantity sensor according to a first embodiment will be described with reference to the drawings. FIG. 1 is a plan view schematically showing the physical quantity sensor 100 according to the first embodiment. FIG. 2 is a cross-sectional view schematically showing the physical quantity sensor 100 according to the first embodiment, taken along line II-II of FIG. 1. In FIGS. 1 and 2, the X-axis (first axis), the Y-axis (second axis), and the Z-axis (third axis) are illustrated as three axes perpendicular to each other.

As shown in FIGS. 1 and 2, the physical quantity sensor 100 can include a substrate 10 and a functional element 20. Further, the physical quantity sensor 100 can include wirings 70, 71, and 72, connection terminals 73, 74, and 75, and a lid 80. For convenience sake, the lid 80 is illustrated in a perspective manner in FIG. 1.

The material of the substrate 10 is, for example, glass or silicon. As shown in FIG. 2, the substrate 10 has a first surface 11 and a second surface 12 on the side opposed to the first surface 11. In the first surface 11, a recess 14 is disposed. Above the recess 14, spring portions 30, 32, 34, and 36 as connection members and a movable body 26 of the functional element 20 are disposed via a space. The movable body 26 includes movable electrode portions 50. The movable body 26 can move to a desired direction due to the recess 14 without being obstructed by the substrate 10. The planar shape (shape as viewed from the Z-axis direction) of the recess 14 is not particularly limited, but is an oblong in the example shown in FIG. 1. The recess 14 is formed by, for example, a photolithographic technique and an etching technique.

The functional element 20 is supported on the first surface 11 (on the substrate 10) of the substrate 10. The functional element 20 is accommodated in a cavity 82 surrounded by the substrate 10 and the lid 80. In the following, a case will be described in which the functional element 20 is an acceleration sensor element (electrostatic capacitive MEMS acceleration sensor element) that detects acceleration in the horizontal direction (direction along the X-axis (the X-axis direction)).

As shown in FIG. 1, the functional element 20 can include a support body 21 having a fixed portion 23 and wall portions 40 and 42, a support body 22 having a fixed portion 24 and wall portions 44 and 46, the movable body 26 having a movable portion 27 and the movable electrode portions 50, the spring portions 30, 32, 34, and 36, and fixed electrode portions 52 and 54.

The movable body 26 is displaced in the X-axis direction (the positive X-direction or the negative X-direction) according to acceleration in the X-axis direction while elastically deforming the spring portions 30, 32, 34, and 36. With such displacement, the sizes of a gap between the movable electrode portion 50 and the fixed electrode portion 52 and a gap between the movable electrode portion 50 and the fixed electrode portion 54 are changed. That is, with such displacement, the magnitudes of an electrostatic capacitance between the movable electrode portion 50 and the fixed electrode portion 52 and an electrostatic capacitance between the movable electrode portion 50 and the fixed electrode portion 54 are changed. Based on changes in these electrostatic capacitances, the functional element 20 (the physical quantity sensor 100) can detect acceleration in the X-axis direction.

The fixed portions 23 and 24 are bonded (fixed) to the first surface 11 of the substrate 10. The fixed portion 23 is disposed on one side (the negative X-direction side) with respect to the recess 14, while the fixed portion 24 is disposed on the other side (the positive X-direction side) with respect to the recess 14. The spring portions 30 and 32 are connected to the fixed portion 23. The spring portions 34 and 36 are connected to the fixed portion 24. In the illustrated example, the fixed portions 23 and 24 are disposed, in plan view, so as to stride over the outer circumferential edge of the recess 14. The planar shape of the fixed portions 23 and 24 is, for example, a rectangle.

The movable portion 27 is disposed between the fixed portion 23 and the fixed portion 24. In the example shown in FIG. 1, the planar shape of the movable portion 27 is an oblong having long sides along the X-axis.

The spring portions 30 and 32 connect the fixed portion 23 with an end 26a (end in the negative X-direction) of the movable body 26. The spring portions 30 and 32 are configured to be able to displace the movable body 26 in the X-axis direction. More specifically, the spring portions 30 and 32 have a shape extending in the X-axis direction while reciprocating in the Y-axis direction. The spring portion 30 is located on the positive Y-direction side of the spring portion 32.

The spring portion 30 includes a first extending portion 31a extending from the fixed portion 23 along the Y-axis direction (in the positive Y-direction), a first turn-around portion (turn-around portion) 31b connected to the first extending portion 31a, and a second extending portion 31c extending from the first turn-around portion 31b along the Y-axis direction (in the negative Y-direction). Further, in the illustrated example, the spring portion 30 includes a second turn-around portion 31d connected to the second extending portion 31c, a third extending portion 31e extending from the second turn-around portion 31d in the positive Y-direction, a third turn-around portion 31f connected to the third extending portion 31e, and a fourth extending portion 31g extending from the third turn-around portion 31f in the negative Y-direction and connected to the movable body 26. The turn-around portions 31b, 31d, and 31f extend along the X-axis.

In the illustrated example, the spring portion 30 and the spring portion 32 are disposed symmetrically with respect to a line (not shown) passing through a center C of the functional element 20 and parallel to the X-axis. Similarly to the spring portion 30, the spring portion 32 can have extending portions 31a, 31c, 31e, and 31g and turn-around portions 31b, 31d, and 31f.

The spring portions 34 and 36 connect the fixed portion 24 with an end 26b (end in the positive X-direction) of the movable body 26. The end 26b is an end of the movable body 26 (of the movable portion 27) on the positive X-direction side. The spring portions 34 and 36 are configured to be able to displace the movable body 26 in the X-axis direction. More specifically, the spring portions 34 and 36 have a shape extending in the X-axis direction while reciprocating in the Y-axis direction. The spring portion 34 is located on the positive Y-direction side of the spring portion 36.

In the illustrated example, the spring portion 30 and the spring portion 34 are disposed symmetrically with respect to a line (not shown) passing through the center C of the functional element 20 and parallel to the Y-axis. Similarly to the spring portion 30, the spring portion 34 can have extending portions 31a, 31c, 31e, and 31g and turn-around portions 31b, 31d, and 31f.

Moreover, the spring portion 34 and the spring portion 36 are disposed symmetrically with respect to the line (not shown) passing through the center C of the functional element 20 and parallel to the X-axis. Similarly to the spring portion 30, the spring portion 36 can have extending portions 31a, 31c, 31e, and 31g and turn-around portions 31b, 31d, and 31f.

The wall portion 40 is disposed, in plan view, outside the first extending portion 31a and the first turn-around portion 31b of the spring portion 30. More specifically, the wall portion 40 includes a first wall portion 40a disposed along the first extending portion 31a of the spring portion 30 in plan view and a second wall portion 40b disposed along the first turn-around portion 31b of the spring portion 30 in plan view. In the illustrated example, the first wall portion 40a extends from the fixed portion 23 in the positive Y-direction. The second wall portion 40b extends from the first wall portion 40a in the positive X-direction. An end (end face facing in the positive X-direction) 40c of the second wall portion 40b in the positive X-direction and an edge (edge face facing in the positive X-direction) 30a of the spring portion 30 in the positive X-direction are located on, for example, the same plane (on a plane parallel to the YZ-plane). The wall portion 40 is disposed between, for example, the spring portion 30 and the wiring 71.

The wall portion 42 is disposed, in plan view, outside the first extending portion 31a and the first turn-around portion 31b of the spring portion 32. More specifically, the wall portion 42 includes a first wall portion 42a disposed along the first extending portion 31a of the spring portion 32 in plan view and a second wall portion 42b disposed along the first turn-around portion 31b of the spring portion 32 in plan view. In the illustrated example, the first wall portion 42a extends from the fixed portion 23 in the negative Y-direction. The second wall portion 42b extends from the first wall portion 42a in the positive X-direction. An end 42c of the second wall portion 42b in the positive X-direction and an edge 32a of the spring portion 32 in the positive X-direction are located on, for example, the same plane.

The wall portion 44 is disposed, in plan view, outside the first extending portion 31a and the first turn-around portion 31b of the spring portion 34. More specifically, the wall portion 44 includes a first wall portion 44a disposed along the first extending portion 31a of the spring portion 34 in plan view and a second wall portion 44b disposed along the first turn-around portion 31b of the spring portion 34 in plan view. In the illustrated example, the first wall portion 44a extends from the fixed portion 24 in the positive Y-direction. The second wall portion 44b extends from the first wall portion 44a in the negative X-direction. An end (end face facing in the negative X-direction) 44c of the second wall portion 44b in the negative X-direction and an edge (edge face facing in the negative X-direction) 34a of the spring portion 34 in the negative X-direction are disposed on, for example, the same plane. The wall portion 44 is disposed between, for example, the spring portion 34 and the wiring 71.

The wall portion 46 is disposed, in plan view, outside the first extending portion 31a and the first turn-around portion 31b of the spring portion 36. More specifically, the wall portion 46 includes a first wall portion 46a disposed along the first extending portion 31a of the spring portion 36 in plan view and a second wall portion 46b disposed along the first turn-around portion 31b of the spring portion 36 in plan view. In the illustrated example, the first wall portion 46a extends from the fixed portion 24 in the negative Y-direction. Moreover, the second wall portion 46b extends from the first wall portion 46a in the negative X-direction. An end 46c of the second wall portion 46b in the negative X-direction and an edge 36a of the spring portion 36 in the negative X-direction are located on, for example, the same plane. The wall portion 46 is disposed between, for example, the spring portion 36 and the wiring 71.

In the illustrated example, the wall portions 40, 42, 44, and 46 are disposed along the circumference (outer edge) of the recess 14 and bonded (fixed) to the first surface 11 of the substrate 10. Although not shown in the drawing, the wall portions 40, 42, 44, and 46 may be disposed so as to overlap with the recess 14 in plan view. That is, the wall portions 40, 42, 44, and 46 may be apart from the substrate 10.

The wall portion 40 and the wall portion 44 are disposed apart from each other for example, and the fixed electrode portions 52 and 54 are disposed, in plan view, between the wall portion 40 and the wall portion 44. For example, in a form where the wall portions are contiguous, a distance between the wall portion and the fixed electrode portion is reduced, so that a parasitic capacitance is sometimes generated between the wall portion and the fixed electrode portion. Similarly, the wall portion 42 and the wall portion 46 are disposed apart from each other for example, and the fixed electrode portions 52 and 54 are disposed, in plan view, between the wall portion 42 and the wall portion 46.

The movable electrode portions 50 are connected to the movable portion 27. The plurality of movable electrode portions 50 are disposed. The movable electrode portions 50 protrude from the movable portion 27 in the positive Y-direction and the negative Y-direction and are arranged in parallel along the X-axis so as to form a comb-teeth shape. The movable electrode portions 50 are disposed integrally with the movable portion 27.

One end of each of the fixed electrode portions 52 and 54 is bonded as a fixed end to the first surface 11 of the substrate 10, while the other end extends as a free end to the movable portion 27 side. The plurality of fixed electrode portions 52 and the plurality of fixed electrode portions 54 are disposed. The fixed electrode portions 52 are electrically connected with the wiring 71, while the fixed electrode portions 54 are electrically connected with the wiring 72. The fixed electrode portions 52 and 54 are alternately arranged in parallel along the X-axis so as to form a comb-teeth shape. The fixed electrode portions 52 and 54 are disposed to face the movable electrode portions 50 with a distance between the fixed electrode portion and the movable electrode portion. The fixed electrode portion 54 is arranged on one side (the negative X-direction side) of the movable electrode portion 50, while the fixed electrode portion 52 is arranged on the other side (the positive X-direction side).

The fixed portions 23 and 24, the movable body 26, the spring portions 30, 32, 34, and 36, and the wall portions 40, 42, 44, and 46 are integrally disposed. The material of the functional element 20 is, for example, silicon doped with an impurity such as phosphorus or boron to provide electrical conductivity. The wall portions 40 and 42 are electrically connected with the spring portions 30 and 32 via the fixed portion 23. The wall portions 44 and 46 are electrically connected with the spring portions 34 and 36 via the fixed portion 24. More specifically, the fixed portions 23 and 24, the movable portion 27, the spring portions 30, 32, 34, and 36, the wall portions 40, 42, 44, and 46, and the movable electrode portions 50 are electrically connected to each other. Thus, the fixed portions 23 and 24, the movable portion 27, the spring portions 30, 32, 34, and 36, the wall portions 40, 42, 44, and 46, and the movable electrode portions 50 can have, for example, the same potential.

A method for bonding the fixed portions 23 and 24 and the fixed electrode portions 52 and 54 of the functional element 20 with the substrate 10 is not particularly limited. However, when, for example, the material of the substrate 10 is glass and the material of the functional element 20 is silicon, the substrate 10 and the functional element 20 can be anodically bonded together.

The functional element 20 is formed by, for example, processing a silicon substrate (not shown) using a photolithographic technique and an etching technique.

Groove portions 15, 16, and 17 are disposed in the first surface 11 of the substrate 10. The groove portion 15 has a planar shape corresponding to, for example, the planar shapes of the wiring 70 and the connection terminal 73. The groove portion 16 has a planar shape corresponding to, for example, the planar shapes of the wiring 71 and the connection terminal 74. The groove portion 17 has a planar shape corresponding to, for example, the planar shapes of the wiring 72 and the connection terminal 75. In the example shown in FIG. 1, the groove portions 16 and 17 are disposed so as to be along the outer circumference of the recess 14.

The depth (size in the Z-axis direction) of the groove portions 15, 16, and 17 is greater than the thicknesses (size in the Z-axis direction) of the wirings 70, 71, and 72 and the connection terminals 73, 74, and 75. With this configuration, the wirings 70, 71, and 72 and the connection terminals 73, 74, and 75 can be prevented from protruding higher (the positive Z-direction) than the first surface 11. The groove portions 15, 16, and 17 are formed by, for example, a photolithographic technique and an etching technique.

The wiring 70 is disposed within the groove portion 15 on the substrate 10. More specifically, the wiring 70 is disposed on a surface of the substrate 10, the surface defining a bottom surface of the groove portion 15. The wiring 70 electrically connects the fixed portion 23 with the connection terminal 73 via a contact portion 76 disposed within the groove portion 15. For example, by applying a voltage to the connection terminal 73, the potentials of the fixed portions 23 and 24, the movable portion 27, the spring portions 30, 32, 34, and 36, the wall portions 40, 42, 44, and 46, and the movable electrode portions 50 can be fixed at the same potential.

The wiring 71 is disposed within the groove portion 16 on the substrate 10. More specifically, the wiring 71 is disposed on a surface of the substrate 10, the surface defining a bottom surface of the groove portion 16. The wiring 71 electrically connects the fixed electrode portion 52 with the connection terminal 74 via a contact portion 77.

The wiring 72 is disposed within the groove portion 17 on the substrate 10. More specifically, the wiring 72 is disposed on a surface of the substrate 10, the surface defining a bottom surface of the groove portion 17. The wiring 72 electrically connects the fixed electrode portion 54 with the connection terminal 75 via a contact portion 78.

The material of the wirings 70, 71, and 72 and the connection terminals 73, 74, and 75 is, for example, ITO (Indium Tin Oxide), aluminum, gold, platinum, titanium, tungsten, or chromium. The material of the contact portions 76, 77, and 78 is, for example, gold, copper, aluminum, platinum, titanium, tungsten, or chromium. In the case where the material of the wirings 70, 71, and 72 and the connection terminals 73, 74, and 75 is a transparent electrode material such as ITO, when the substrate 10 is transparent, a foreign substance existing on, for example, the wirings 70, 71, and 72 or on the connection terminals 73, 74, and 75 can be visually recognized easily from the second surface 12 side of the substrate 10.

The wirings 70, 71, and 72, the connection terminals 73, 74, and 75, and the contact portions 76, 77, and 78 are formed by, for example, a sputtering method or a CVD (Chemical Vapor Deposition) method.

In the physical quantity sensor 100, an electrostatic capacitance between the movable electrode portion 50 and the fixed electrode portion 52 can be measured using the connection terminals 73 and 74. Further, in the physical quantity sensor 100, an electrostatic capacitance between the movable electrode portion 50 and the fixed electrode portion 54 can be measured using the connection terminals 73 and 75. In the physical quantity sensor 100 as described above, the electrostatic capacitance between the movable electrode portion 50 and the fixed electrode portion and the electrostatic capacitance between the movable electrode portion 50 and the fixed electrode portion 54 are separately measured, and based on the results of the measurement, a physical quantity (acceleration) can be detected with high accuracy.

The lid 80 is disposed on the substrate 10. The substrate 10 and the lid 80 can constitute a package. The substrate 10 and the lid 80 can form a cavity 82. The functional element 20 can be accommodated in the cavity 82. For example, a void (void within the groove portion 15) between the wiring 70 and the lid 80 shown in FIG. 2 may be filled with an adhesive member or the like. In this case, the cavity 82 may be hermetically sealed in, for example, an inert gas (for example, nitrogen gas) atmosphere.

The material of the lid 80 is, for example, silicon or glass. A method for bonding the lid 80 with the substrate 10 is not particularly limited. However, when, for example, the material of the substrate 10 is glass and the material of the lid 80 is silicon, the substrate 10 and the lid 80 can be anodically bonded together.

The physical quantity sensor 100 according to the first embodiment has, for example, the following features.

The physical quantity sensor 100 includes the spring portion 30 and the wall portion 40. The spring portion 30 connects the fixed portion 23 with the end 26a of the movable body 26 and includes the first extending portion 31a extending from the fixed portion 23 along the Y-axis, the turn-around portion 31b connected to the first extending portion 31a, and the second extending portion 31c extending from the turn-around portion 31b along the Y-axis. The wall portion 40 extends from the fixed portion 23 and is disposed, in plan view, outside the first extending portion 31a and the turn-around portion 31b of the spring portion 30. Then, the spring portion 30 and the wall portion 40 are electrically connected. Therefore, the exertion of an electrostatic force on the spring portion 30 due to a member (for example, another functional element or the like accommodated in the cavity 82) having a potential different from that of the spring portion 30 can be prevented by the wall portion 40. With this configuration, the movable body 26 can operate stably, so that the lowering of the sensitivity, for example, can be prevented.

Similarly, the physical quantity sensor 100 includes the spring portion 32 connecting the fixed portion 23 with the end 26a of the movable body 26 and the spring portions 34 and 36 connecting the fixed portion 24 with the end 26b of the movable body 26. The spring portions 32, 34, and 36 have the first extending portions 31a extending from the fixed portions 23 and 24 along the Y-axis, the turn-around portions 31b connected to the first extending portions 31a, and the second extending portions 31c extending from the turn-around portions 31b along the Y-axis. Further, the physical quantity sensor 100 includes the wall portions 42, 44, and 46 extending from the fixed portions 23 and 24 and disposed, in plan view, outside the first extending portions 31a and the turn-around portions 31b of the spring portions 32, 34, and 36. Then, the spring portions 32, 34, and 36 and the wall portions 42, 44, and 46 are electrically connected. Therefore, for example, the exertion of an electrostatic force on the spring portions 32, 34, and 36 due to another functional element or the like can be prevented by the wall portions 42, 44, and 46.

Further, according to the physical quantity sensor 100, since the spring portions 30, 32, 34, and 36 and the wall portions 40, 42, 44, and 46 are electrically connected, there is no need to dispose a dedicated connection terminal for fixing the potential of the wall portion. In the physical quantity sensor 100, by applying a voltage to one connection terminal 73, the potentials of the spring portions 30, 32, 34, and 36 and the wall portions 40, 42, 44, and 46 can be fixed at, for example, the same potential. Therefore, in the physical quantity sensor 100, an increase in the number of wirings or connection terminals for fixing the potentials of the wall portions 40, 42, 44, and 46 can be prevented, so that a reduction in size can be achieved.

In the physical quantity sensor 100 as described above, the exertion of an electrostatic force on the spring portions 30, 32, 34, and 36 can be prevented while achieving a reduction in size.

According to the physical quantity sensor 100, the wall portions 40, 42, 44, and 46 include the first wall portions 40a, 42a, 44a, and 46a disposed along the first extending portions 31a in plan view and the second wall portions 40b, 42b, 44b, and 46b disposed along the turn-around portions 31b in plan view. Therefore, for example, the exertion of an electrostatic force on the spring portions 30, 32, 34, and 36 due to another functional element or the like can be prevented more reliably by the wall portions 40, 42, 44, and 46.

According to the physical quantity sensor 100, the wall portions 40, 44, and 46 are disposed between the spring portions 30, 34, and 36 and the wiring 71 electrically connected to the fixed electrode portions 52. The wiring 71 has a potential different from those of the spring portions 30, 34, and 36. Therefore, the exertion of an electrostatic force on the spring portions 30, 34, and 36 due to the wiring 71 can be prevented by the wall portions 40, 44, and 46.

According to the physical quantity sensor 100, the recess 14 is disposed in the substrate 10; the movable body 26 is arranged above the recess 14; and the wall portions 40, 42, 44, and 46 are arranged along the outer edge of the recess 14. Therefore, for example, the entire rear surfaces (lower surfaces) of the wall portions 40, 42, 44, and 46 can be fixed (bonded) to the first surface 11 of the substrate 10. With this configuration, the contact area between the wall portions 40, 42, 44, and 46 and the substrate 10 can be increased, so that the wall portions 40, 42, 44, and 46 can be stably fixed. Moreover, for example, there is no need to, in a substrate where a recess is not disposed, separate the movable body from the substrate via a spacer member. Therefore, the number of members can be reduced, so that a reduction in cost, for example, can be achieved.

According to the physical quantity sensor 100, the fixed portions 23 and 24, the movable body 26, the spring portions 30, 32, 34, and 36, and the wall portions 40, 42, 44, and 46 are integrally disposed. Therefore, the functional element 20 can be integrally formed by, for example, processing a silicon substrate (not shown). With this configuration, for example, a fine processing technique used in the manufacture of silicon semiconductor devices is applicable, so that a reduction in the size of the functional element 20 can be achieved.

According to the physical quantity sensor 100, the end 40c of the second wall portion 40b in the positive X-direction and the edge 30a of the spring portion 30 in the positive X-direction are located on the same plane. With this configuration, compared to, for example, the case where the end of the second wall portion in the positive X-direction is located on the negative X-direction side of the edge of the spring portion in the positive X-direction, the exertion of an electrostatic force on the spring portion 30 can be prevented more reliably by the wall portion 40.

Similarly, in the physical quantity sensor 100, the ends 42c, 44c, and 46c of the second wall portions 42b, 44b, and 46b and the edges 32a, 34a, and 36a of the spring portions 32, 34, and 36 are located on the same plane. With this configuration, the exertion of an electrostatic force on the spring portions 32, 34, and 36 can be prevented more reliably by the wall portions 42, 44, and 46.

### 1.2. First Modified Example

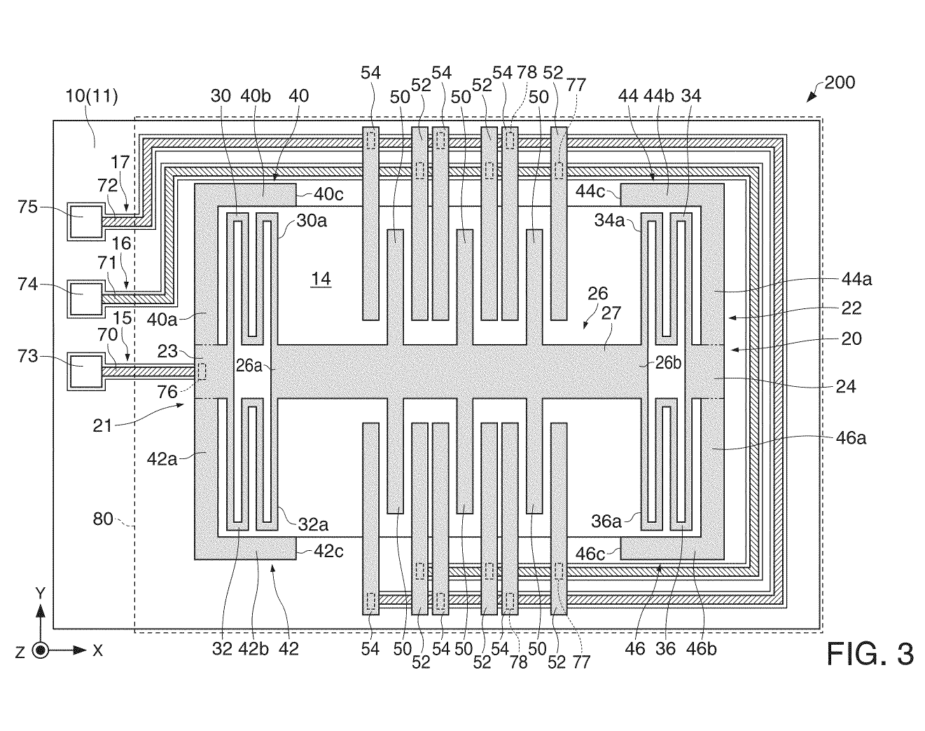

Next, a physical quantity sensor according to a first modified example of the first embodiment will be described with reference to the drawing. FIG. 3 is a plan view schematically showing the physical quantity sensor 200 according to the first modified example of the first embodiment. In FIG. 3, the X-axis, the Y-axis, and the Z-axis are illustrated as three axes perpendicular to each other. Moreover, for convenience sake, the lid 80 is illustrated in a perspective manner in FIG. 3. Hereinafter, in the physical quantity sensor 200, members having functions similar to those of the constituent members of the physical quantity sensor 100 described above are denoted by the same reference numerals and signs, and the detailed descriptions thereof are omitted.

In the physical quantity sensor 100 as shown in FIG. 1, the ends 40c, 42c, 44c, and 46c of the second wall portions 40b, 42b, 44b, and 46b are located on the same plane as the edges 30a, 32a, 34a, and 36a of the spring portions 30, 32, 34, and 36.

In contrast to this, in the physical quantity sensor 200 as shown in FIG. 3, the end 40c of the second wall portion 40b of the wall portion 40 is located on the movable body 26 side of the edge 30a of the spring portion 30 in the X-axis direction. More specifically, the end face 40c is located on the positive X-direction side of the edge face 30a.

Similarly, the end 42c is located on the movable body side of the edge 32a in the X-axis direction. More specifically, the end 42c is located on the positive X-direction side of the edge 32a. The end 44c is located on the movable body 26 side of the edge 34a in the X-axis direction. More specifically, the end 44c is located on the negative X-direction side of the edge 34a. The end 46c is located on the movable body 26 side of the edge 36a in the X-axis direction. More specifically, the end 46c is located on the negative X-direction side of the edge 36a.

In the illustrated example, the end 26a of the movable body 26 to which the spring portions 30 and 32 are connected is located on the first wall portion 40a side of the end 40c of the second wall portion 40b in the X-axis direction. Moreover, the end 26a is located on the first wall portion 42a side of the end 42c of the second wall portion 42b in the X-axis direction. More specifically, the end 26a is located on the negative X-direction side of the ends 40c and 42c.

Similarly, the end 26b of the movable body 26 to which the spring portions 34 and 36 are connected is located on the first wall portion 44a side of the end 44c of the second wall portion 44b in the X-axis direction. Moreover, the end 26b is located on the first wall portion 46a side of the end 46c of the second wall portion 46b in the X-axis direction. More specifically, the end 26b is located on the positive X-direction side of the ends 44c and 46c.

According to the physical quantity sensor 200, compared to the physical quantity sensor 100, the exertion of an electrostatic force on the spring portions 30, 32, 34, and 36 can be prevented more reliably by the wall portions 40, 42, 44, and 46.

### 1.3. Second Modified Example

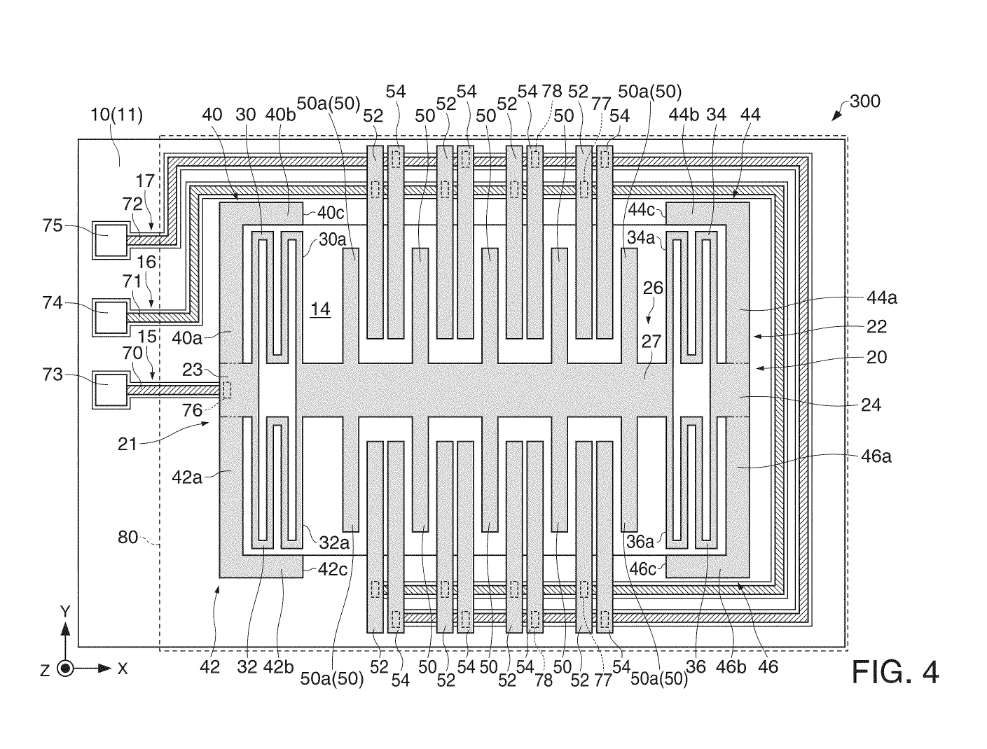

Next, a physical quantity sensor according to a second modified example of the first embodiment will be described with reference to the drawing. FIG. 4 is a plan view schematically showing the physical quantity sensor 300 according to the second modified example of the first embodiment. In FIG. 4, the X-axis, the Y-axis, and the Z-axis are illustrated as three axes perpendicular to each other. Moreover, for convenience sake, the lid 80 is illustrated in a perspective manner in FIG. 4. Hereinafter, in the physical quantity sensor 300, members having functions similar to those of the constituent members of the physical quantity sensor 100 described above are denoted by the same reference numerals and signs, and the detailed descriptions thereof are omitted.

In the physical quantity sensor 100 as shown in FIG. 1, the movable electrode portion 50 is interposed between the fixed electrode portion 52 and the fixed electrode portion 54.

In contrast to this, in the physical quantity sensor 300 as shown in FIG. 4, movable electrode portions 50a each of which is not interposed between the fixed electrode portion 52 and the fixed electrode portion 54 are provided. More specifically, the plurality of movable electrode portions 50 and the plurality of fixed electrode portions 52 and 54 are aligned in a line along the X-axis, and at the outermosts of the line of the movable electrode portions 50 and the fixed electrode portions 52 and 54, the movable electrode portions 50a are disposed. That is, the movable electrode portions 50a are arranged next to the spring portions 30, 32, 34, and 36. The movable electrode portions 50a are arranged to face the spring portions 30, 32, 34, and 36 via voids. The fixed electrode portions 52 and 54 are not arranged between the movable electrode portions 50a and the spring portions 30, 32, 34, and 36. The movable electrode portions 50a are electrically connected with the spring portions 30, 32, 34, and 36 via the movable portion 27.

According to the physical quantity sensor 300, the exertion of an electrostatic force on the spring portions 30, 32, 34, and 36 due to the fixed electrode portions 52 and 54 having a potential different from those of the spring portions 30, 32, 34, and 36 can be prevented by the movable electrode portions 50a. Further, according to the physical quantity sensor 300, compared to the physical quantity sensor 100, the numbers of the movable electrode portions 50 and the fixed electrode portions 52 and 54 can be increased, so that the detection sensitivity can be improved.

### 2. Second Embodiment

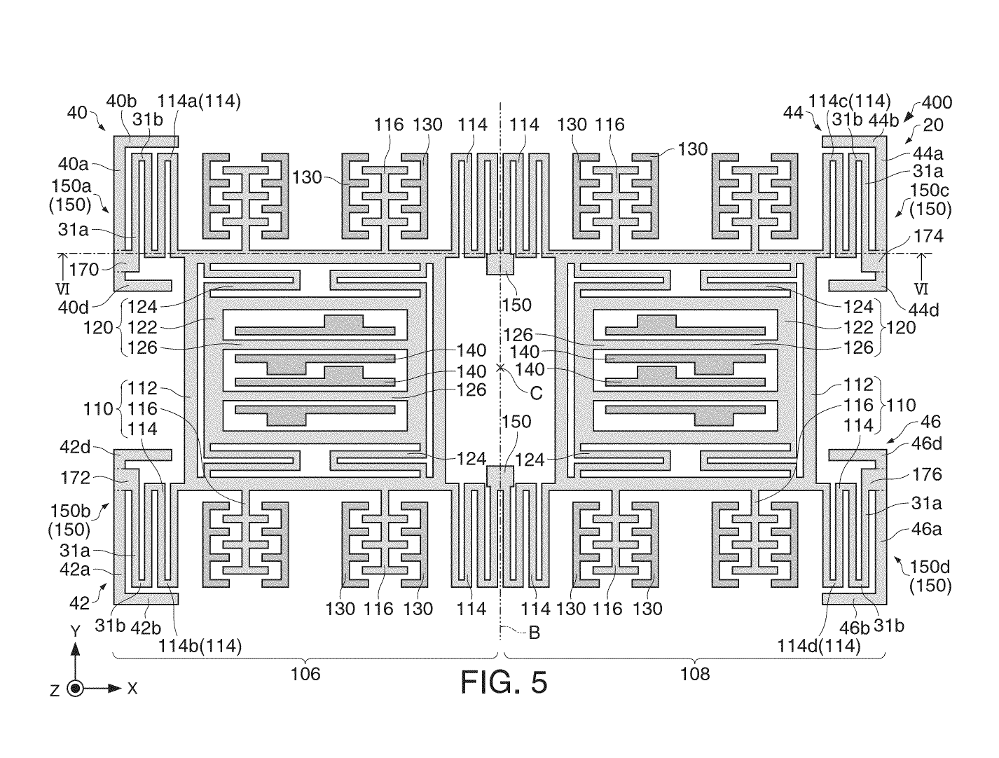

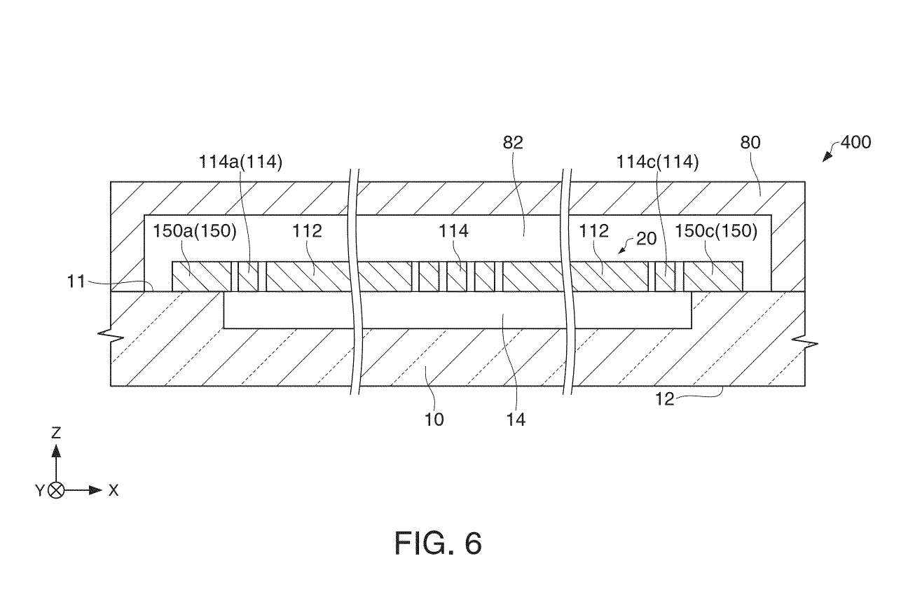

Next, a physical quantity sensor according to a second embodiment will be described with reference to the drawings. FIG. 5 is a plan view schematically showing the physical quantity sensor 400 according to the second embodiment. FIG. 6 is a cross-sectional view schematically showing the physical quantity sensor 400 according to the second embodiment, taken along line VI-VI of FIG. 5. In FIGS. 5 and 6, the X-axis, the Y-axis, and the Z-axis are illustrated as three axes perpendicular to each other. Moreover, for convenience sake, the illustration of the substrate 10 and the lid 80 is omitted in FIG. 5. Hereinafter, differences of the physical quantity sensor 400 from the example of the physical quantity sensor 100 described above will be described, and the description of similarities is omitted.

In the physical quantity sensor 100, the functional element 20 is an acceleration sensor element (electrostatic capacitive MEMS acceleration sensor element) that detects acceleration in the horizontal direction (the X-axis direction). In contrast to this, in the physical quantity sensor 400, the functional element 20 is a gyro sensor element (electrostatic capacitive MEMS gyro sensor element) that detects angular velocity about the Z-axis.

As shown in FIGS. 5 and 6, the functional element 20 can have a first vibrating body 106, a second vibrating body 108, driving fixed electrode portions 130, detecting fixed electrode portions (fixed electrode portions) 140, and support bodies 150.

The vibrating bodies 106 and 108 are supported by the support bodies 150 bonded (fixed) to the first surface 11 of the substrate 10 and arranged apart from the substrate 10. More specifically, the vibrating bodies 106 and 108 are disposed above the recess 14 disposed in the substrate 10 via a space. The first vibrating body 106 and the second vibrating body 108 are coupled with each other along the X-axis. As shown in FIG. 5, the first vibrating body 106 and the second vibrating body 108 can have a shape symmetrical with respect to a border line B (line along the Y-axis) therebetween.

Each of the vibrating bodies 106 and 108 has a driving portion 110 and a detecting portion 120. The driving portion 110 can have a driving support portion 112, driving spring portions (spring portions) 114, and driving movable electrode portions 116. The detecting portion 120 can have a detecting support portion 122, detecting spring portions 124, and detecting movable electrode portions (movable electrode portions) 126. The driving support portion 112, the driving movable electrode portions 116, the detecting support portion 122, the detecting spring portions 124, and the detecting movable electrode portions 126 constitute a movable body displaceable in the X-axis direction.

The driving support portion 112 has, for example, a frame-like shape, and the detecting portion 120 is arranged inside the driving support portion 112.

The driving spring portions 114 are arranged outside the driving support portion 112. In the illustrated example, one end of the driving spring portion 114 is connected to the driving support portion 112, while the other end of the driving spring portion 114 is connected to the support body 150.

The driving spring portions 114 are configured to be able to displace the driving support portion 112 in the X-axis direction. More specifically, the driving spring portion 114 has a shape extending in the X-axis direction while reciprocating in the Y-axis direction.

In the illustrated example, four driving spring portions 114 are disposed in the first vibrating body 106. Therefore, the first vibrating body 106 is supported by four support bodies 150. Similarly, the second vibrating body 108 is supported by four support bodies 150. The support body 150 on the border line B between the first vibrating body 106 and the second vibrating body 108 is the support body 150 common to the vibrating bodies 106 and 108. The support body 150 on the border line B may not be disposed.

Support bodies 150a and 150b (support portions not disposed on the border line B) of the four support bodies 150 of the first vibrating body 106 have fixed portions 170 and 172 and the wall portions 40 and 42.

The fixed portions 170 and 172 are bonded (fixed) to the first surface 11 of the substrate 10. The planar shape of the fixed portions 170 and 172 is, for example, a rectangle.

The wall portion 40 is disposed, in plan view, outside the first extending portion 31a and the first turn-around portion 31b of a driving spring portion 114a. The driving spring portion 114a connects the fixed portion 170 with an end of the driving support portion 112. The driving spring portion 114a has the same shape as that of the spring portion 30 of the physical quantity sensor 100 according to the first embodiment.

In the illustrated example, the wall portion 40 further has a third wall portion 40d extending from the fixed portion 170 and arranged to face the second wall portion 40b via the driving spring portion 114a. The wall portion 40 is electrically connected with the driving spring portion 114a via the fixed portion 170.

The wall portion 42 is disposed, in plan view, outside the first extending portion 31a and the first turn-around portion 31b of a driving spring portion 114b. The driving spring portion 114b connects the fixed portion 172 with an end of the driving support portion 112. In the illustrated example, the driving spring portion 114a and the driving spring portion 114b are disposed symmetrically with respect to the line (not shown) passing through the center C of the functional element 20 and parallel to the X-axis.

In the illustrated example, the wall portion 42 further has a third wall portion 42d extending from the fixed portion 172 and arranged to face the second wall portion 42b via the driving spring portion 114b. The wall portion 42 is electrically connected with the driving spring portion 114b via the fixed portion 172.

Support bodies 150c and 150d (support portions not disposed on the border line B) of the four support bodies 150 of the second vibrating body 108 have fixed portions 174 and 176 and the wall portions 44 and 46.

The fixed portions 174 and 176 are bonded (fixed) to the first surface 11 of the substrate 10. The planar shape of the fixed portions 174 and 176 is, for example, a rectangle.

The wall portion 44 is disposed, in plan view, outside the first extending portion 31a and the first turn-around portion 31b of a driving spring portion 114c. The driving spring portion 114c connects the fixed portion 174 with an end of the driving support portion 112. In the illustrated example, the driving spring portion 114a and the driving spring portion 114c are disposed symmetrically with respect to the line (not shown) passing through the center C of the functional element 20 and parallel to the Y-axis.

In the illustrated example, the wall portion 44 further has a third wall portion 44d extending from the fixed portion 174 and arranged to face the second wall portion 44b via the driving spring portion 114c. The wall portion 44 is electrically connected with the driving spring portion 114c via the fixed portion 174.

The wall portion 46 is disposed, in plan view, outside the first extending portion 31a and the first turn-around portion 31b of a driving spring portion 114d. The driving spring portion 114d connects the fixed portion 176 with an end of the driving support portion 112. In the illustrated example, the driving spring portion 114b and the driving spring portion 114d are disposed symmetrically with respect to the line (not shown) passing through the center C of the functional element 20 and parallel to the Y-axis.

In the illustrated example, the wall portion 46 further has a third wall portion 46d extending from the fixed portion 176 and arranged to face the second wall portion 46b via the driving spring portion 114d. The wall portion 46 is electrically connected with the driving spring portion 114d via the fixed portion 176.

The driving movable electrode portions 116 are arranged outside the driving support portion 112 and connected to the driving support portion 112.

The driving fixed electrode portions 130 are arranged outside the driving support portion 112. The driving fixed electrode portions 130 are bonded (fixed) to the first surface 11 of the substrate 10. The driving fixed electrode portion 130 is arranged to face the driving movable electrode portion 116. In the illustrated example, the plurality of driving fixed electrode portions 130 are disposed. The driving movable electrode portion 116 is disposed between the driving fixed electrode portions 130.

The detecting portion 120 is coupled with the driving portion 110. In the illustrated example, the detecting portion 120 is arranged inside the driving support portion 112. Although not shown in the drawing, the detecting portion 120 may be arranged outside the driving support portion 112 as long as the detecting portion 120 is coupled with the driving portion 110.

The detecting support portion 122 has, for example, a frame-like shape.

The detecting spring portions 124 are arranged outside the detecting support portion 122. The detecting spring portions 124 connect the detecting support portion 122 with the driving support portion 112. More specifically, one end of the detecting spring portion 124 is connected to the detecting support portion 122. The other end of the detecting spring portion 124 is connected to the driving support portion 112.

The detecting spring portions 124 are configured to be able to displace the detecting support portion 122 in the Y-axis direction. More specifically, the detecting spring portion 124 has a shape extending in the Y-axis direction while reciprocating in the X-axis direction.

The detecting movable electrode portions 126 are arranged inside the detecting support portion 122 and connected to the detecting support portion 122. In the illustrated example, the detecting movable electrode portions 126 extend along the X-axis.

The detecting fixed electrode portions 140 are arranged inside the detecting support portion 122. The detecting fixed electrode portions 140 are bonded (fixed) to the first surface 11 of the substrate 10. The detecting fixed electrode portion 140 is disposed to face the detecting movable electrode portion 126. In the illustrated example, the plurality of detecting fixed electrode portions 140 are disposed. The detecting movable electrode portion 126 is disposed between the detecting fixed electrode portions 140.

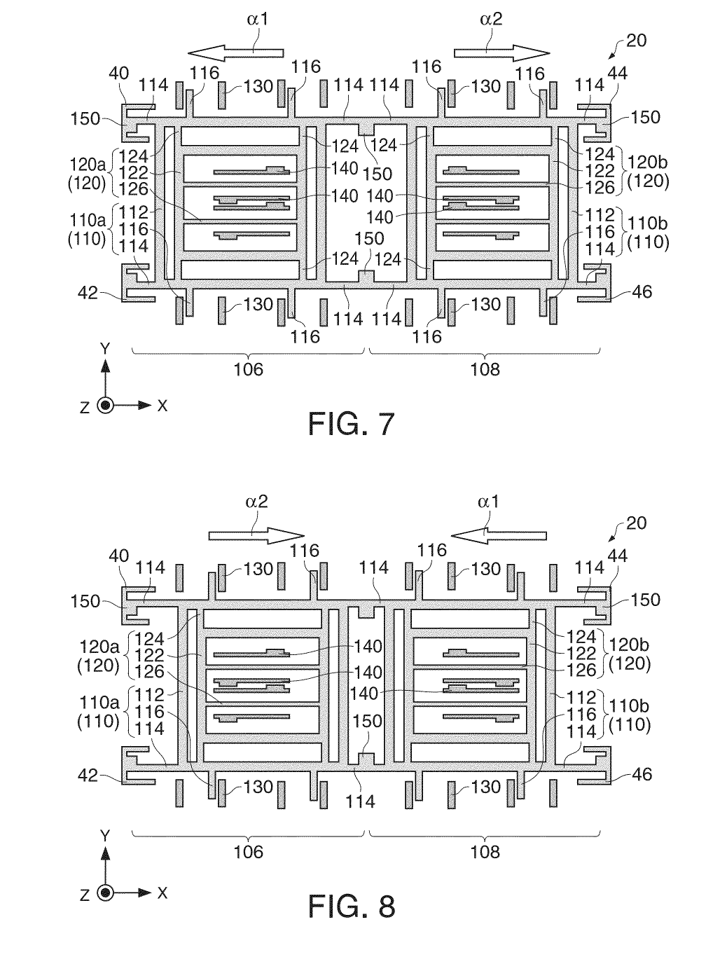

Next, the operations of the functional element 20 will be described. FIGS. 7 to 10 explain the operations of the functional element 20. In FIGS. 7 to 10, the X-axis, the Y-axis, and the Z-axis are illustrated as three axes perpendicular to each other. Moreover, for convenience sake, the portions of the functional element 20 are shown in a simplified manner in FIGS. 7 to 10.

When a voltage is applied to the driving fixed electrode portions 130 and the driving movable electrode portions 116 with a power supply (not shown), an electrostatic force can be generated between the driving fixed electrode portion 130 and the driving movable electrode portion 116. With this configuration, as shown in FIGS. 7 and 8, the driving spring portions 114 can be expanded and contracted along the X-axis, so that the driving portion 110 can be vibrated along the X-axis.

More specifically, a first alternating voltage is applied between the driving movable electrode portion 116 and the driving fixed electrode portion 130 of the first vibrating body 106, while a second alternating voltage whose phase is shifted by 180 degrees from the first alternating voltage is applied between the driving movable electrode portion 116 and the driving fixed electrode portion 130 of the second vibrating body 108. With this configuration, a first driving portion 110a of the first vibrating body 106 and a second driving portion 110b of the second vibrating body 108 can be vibrated along the X-axis in phase opposition at a predetermined frequency. That is, the first driving portion 110a and the second driving portion 110b coupled with each other along the X-axis vibrate in phase opposition along the X-axis. In the example shown in FIG. 7, the first driving portion 110a is displaced in an α1 direction, while the second driving portion 110b is displaced in an α2 direction opposite from the α1 direction. In the example shown in FIG. 8, the first driving portion 110a is displaced in the α2 direction, while the second driving portion 110b is displaced in the α1 direction.

Since the detecting portion 120 is coupled with the driving portion 110, the detecting portion 120 is also displaced along the X-axis with the vibration of the driving portion 110. That is, the first vibrating body 106 and the second vibrating body 108 are displaced in opposite directions along the X-axis.

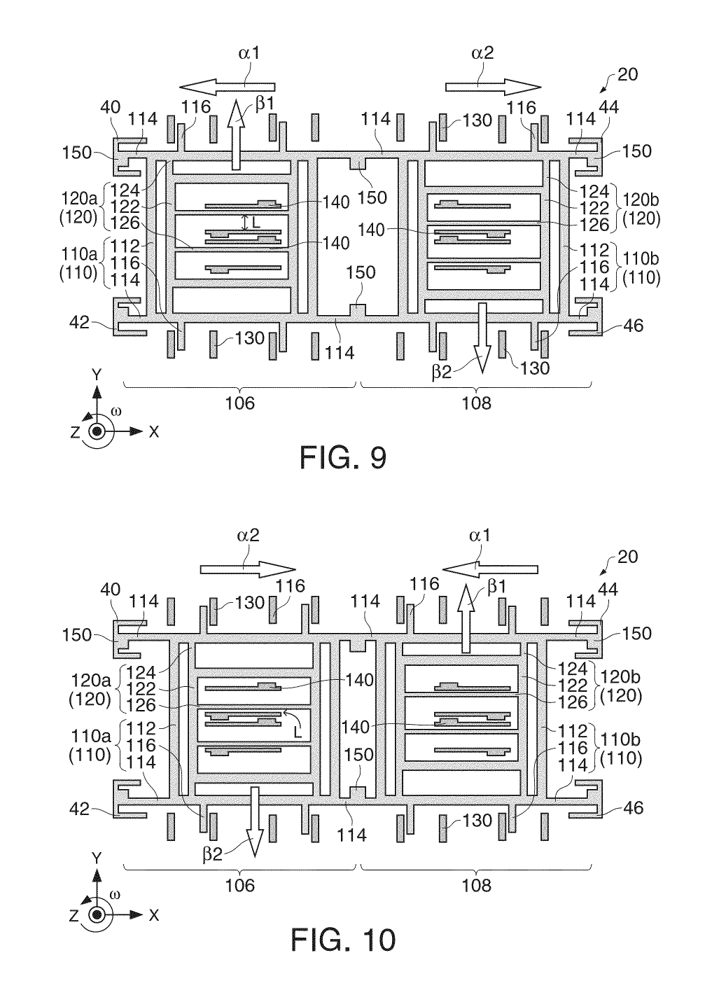

As shown in FIGS. 9 and 10, in a state where the driving portions 110a and 110b vibrate along the X-axis, when an angular velocity ω about the Z-axis is applied to the functional element 20, the Coriolis force acts and thus the detecting portion 120 is displaced along the Y-axis. That is, the first detecting portion 120a coupled with the first driving portion 110a and the second detecting portion 120b coupled with the second driving portion 110b are displaced in opposite directions along the Y-axis. In the example shown in FIG. 8, the first detecting portion 120a is displaced in a β1 direction, while the second detecting portion 120b is displaced in a β2 direction opposite from the β1 direction. In the example shown in FIG. 9, the first detecting portion 120a is displaced in the β2 direction, while the second detecting portion 120b is displaced in the β1 direction.

The detecting portions 120a and 120b are displaced along the Y-axis, so that a distance L between the detecting movable electrode portion 126 and the detecting fixed electrode portion 140 is changed. Therefore, an electrostatic capacitance between the detecting movable electrode portion 126 and the detecting fixed electrode portion 140 is changed. In the functional element 20, by applying a voltage to the detecting movable electrode portion 126 and the detecting fixed electrode portion 140, the amount of change in the electrostatic capacitance between the detecting movable electrode portion 126 and the detecting fixed electrode portion 140 is detected, and thus the angular velocity ω about the Z-axis can be obtained.

According to the physical quantity sensor 400, the exertion of an electrostatic force on the driving spring portions 114a, 114b, 114c, and 114d due to a member (for example, another functional element or the like accommodated in the cavity 82) having a potential different from those of the driving spring portions 114a, 114b, 114c, and 114d can be prevented by the wall portions 40, 42, 44, and 46, similarly to the physical quantity sensor 100. With this configuration, the movable body composed of the driving support portion 112, the driving movable electrode portions 116, the detecting support portion 122, the detecting spring portions 124, and the detecting movable electrode portions 126 can operate stably, so that the lowering of the sensitivity, for example, can be prevented.

Further, according to the physical quantity sensor 400, since the driving spring portions 114a, 114b, 114c, and 114d and the wall portions 40, 42, 44, and 46 are electrically connected, there is no need to dispose a dedicated connection terminal for fixing the potential of the wall portion, similarly to the physical quantity sensor 100. Therefore, in the physical quantity sensor 400, an increase in the number of wirings or connection terminals for fixing the potential of the wall portions 40, 42, 44, and 46 can be prevented, so that a reduction in size can be achieved.

In the physical quantity sensor 400 as described above, the exertion of an electrostatic force on the driving spring portions 114a, 114b, 114c, and 114d can be prevented while achieving a reduction in size.

### 3. Third Embodiment

Next, electronic apparatuses according to a third embodiment will be described with reference to the drawings. The electronic apparatuses according to the third embodiment include any of the physical quantity sensors according to the embodiment of the invention. In the following, electronic apparatuses including the physical quantity sensor 100 as the physical quantity sensor according to the embodiment of the invention will be described.

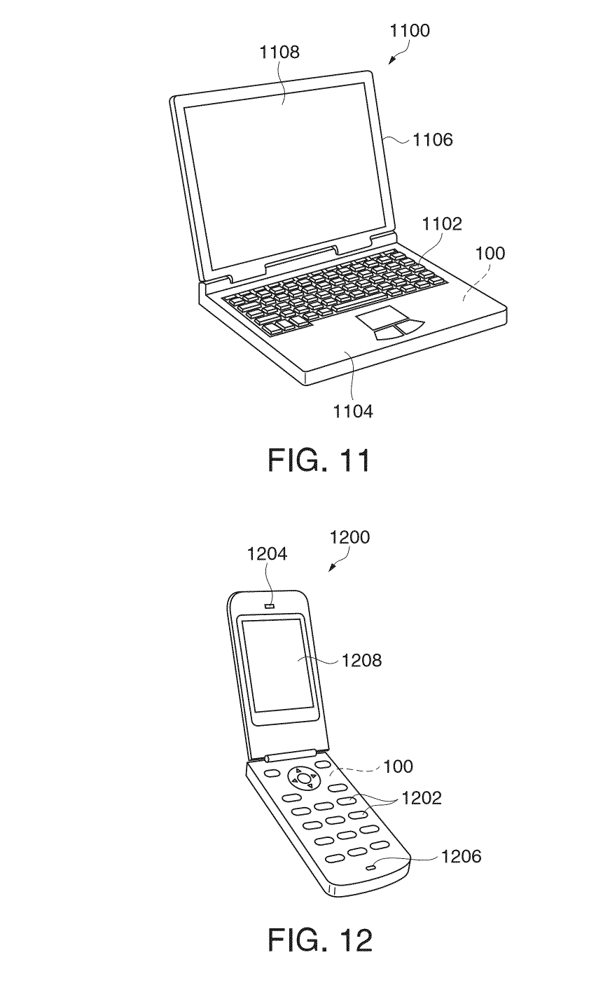

FIG. 11 is a perspective view schematically showing a mobile (or notebook) personal computer 1100 as an electronic apparatus according to the third embodiment.

As shown in FIG. 11, the personal computer 1100 includes a main body portion 1104 including a keyboard 1102 and a display unit 1106 having a display portion 1108. The display unit 1106 is rotationally movably supported relative to the main body portion 1104 via a hinge structure portion.

In the personal computer 1100, the physical quantity sensor 100 is incorporated.

FIG. 12 is a perspective view schematically showing a mobile phone (including a PHS) 1200 as an electronic apparatus according to the third embodiment.

As shown in FIG. 12, the mobile phone 1200 includes a plurality of operation buttons 1202, an earpiece 1204, and a mouthpiece 1206. A display portion 1208 is arranged between the operation buttons 1202 and the earpiece 1204.

In the mobile phone 1200, the physical quantity sensor 100 is incorporated.

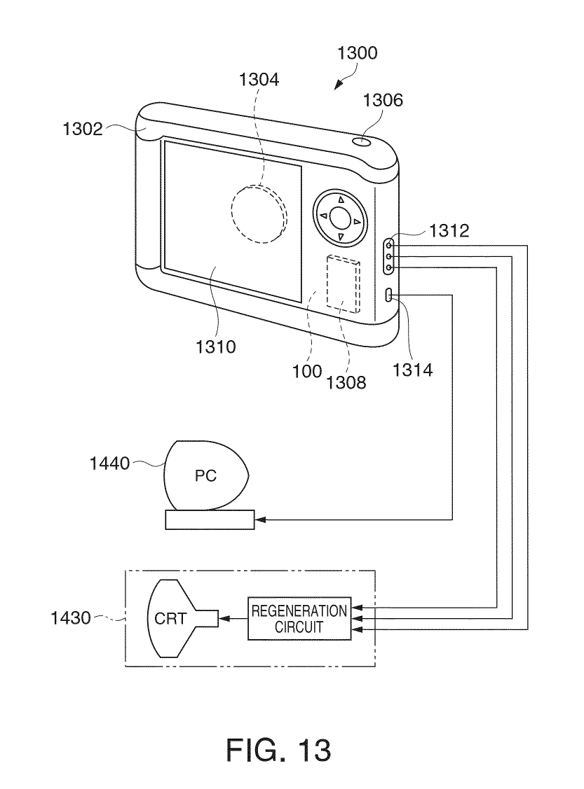

FIG. 13 is a perspective view schematically showing a digital still camera 1300 as an electronic apparatus according to the third embodiment. In FIG. 13, connections with external apparatuses are also shown in a simplified manner.

Here, usual cameras expose a silver halide photographic film with an optical image of a subject, whereas the digital still camera 1300 photoelectrically converts an optical image of a subject with an imaging element such as a CCD (Charge Coupled Device) to generate imaging signals (image signals).

A display portion 1310 is disposed on the back surface of a case (body) 1302 in the digital still camera 1300 and configured to perform display based on imaging signals generated by a CCD. The display portion 1310 functions as a finder that displays a subject as an electronic image.

Moreover, on the front side (the rear side in the drawing) of the case 1302, a light receiving unit 1304 including an optical lens (imaging optical system) and a CCD is disposed.

When a photographer confirms a subject image displayed on the display portion 1310 and presses down a shutter button 1306, imaging signals of a CCD at the time are transferred to and stored in a memory 1308.

Moreover, in the digital still camera 1300, a video signal output terminal 1312 and a data communication input/output terminal 1314 are disposed on the side surface of the case 1302. Then, a television monitor 1430 and a personal computer 1440 are connected as necessary to the video signal output terminal 1312 and the data communication input/output terminal 1314, respectively. Further, the imaging signals stored in the memory 1308 are output to the television monitor 1430 or the personal computer 1440 by a predetermined operation.

In the digital still camera 1300, the physical quantity sensor 100 is incorporated.

The electronic apparatuses 1100, 1200, and 1300 described above can have the physical quantity sensor 100 that can prevent the exertion of an electrostatic force on the spring portion while achieving a reduction in size.

An electronic apparatus including the physical quantity sensor 100 can be applied to for example, in addition to the personal computer (mobile personal computer) shown in FIG. 11, the mobile phone shown in FIG. 12, and the digital still camera shown in FIG. 13, inkjet ejection apparatuses (for example, inkjet printers), laptop personal computers, television sets, video camcorders, video tape recorders, various kinds of navigation systems, pagers, electronic notebooks (including those with communication function), electronic dictionaries, calculators, electronic gaming machines, word processors, workstations, videophones, surveillance television monitors, electronic binoculars, POS terminals, medical equipment (for example, electronic thermometers, sphygmomanometers, blood glucose meters, electrocardiogram measuring systems, ultrasonic diagnosis apparatuses, and electronic endoscopes), fishfinders, various kinds of measuring instrument, indicators (for example, indicators used in vehicles, aircraft, rockets, and ships), the attitude control of robots or the human body, flight simulators, and the like.

The embodiments and modified examples described above are illustrative only, and the invention is not limited to them. For example, each of the embodiments and each of the modified examples can be appropriately combined.

The invention includes a configuration (for example, a configuration having the same function, method, and result, or a configuration having the same advantage and effect) that is substantially the same as those described in the embodiments. Moreover, the invention includes a configuration in which a non-essential portion of the configurations described in the embodiments is replaced. Moreover, the invention includes a configuration providing the same operational effects as those described in the embodiments, or a configuration capable of achieving the same advantages. Moreover, the invention includes a configuration in which a publicly known technique is added to the configurations described in the embodiments.

The entire disclosure of Japanese Patent Application No. 2012-084155, filed Apr. 2, 2012 is expressly incorporated by reference herein.

What is claimed is:

1. A physical quantity sensor comprising:
a movable body including a movable electrode portion and displaceable along a first axis;
a fixed electrode portion disposed to face the movable electrode portion;
a connection member connecting a fixed portion with the movable body and including a first extending portion extending from the fixed portion along a second axis crossing a direction of the first axis, a turn-around portion connected to the first extending portion, and a second extending portion extending from the turn-around portion along the second axis; and
a wall portion extending from the fixed portion and disposed, in plan view, outside the first extending portion and the turn-around portion of the connection member, wherein
the connection member and the wall portion are electrically connected.

2. The physical quantity sensor according to claim 1, wherein
the wall portion includes a first wall portion disposed along the first extending portion in plan view and a second wall portion disposed along the turn-around portion in plan view.

3. The physical quantity sensor according to claim 2, wherein
an end of the movable body to which the connection member is connected is located on the fixed portion side of an end of the second wall portion in the direction of the first axis.

4. The physical quantity sensor according to claim 1, further comprising a wiring electrically connected to the fixed electrode portion, wherein
the wall portion is disposed between the connection member and the wiring.

5. The physical quantity sensor according to claim 1, wherein
the movable electrode portion is arranged next to the connection member.

6. The physical quantity sensor according to claim 1, further comprising a substrate to which the fixed portion and the fixed electrode are fixed, wherein
a recess is disposed in the substrate,
the movable body is arranged above the recess, and
the wall portion is arranged along the outer edge of the recess.

7. The physical quantity sensor according to claim 1, wherein
the fixed portion, the movable body, the connection member, and the wall portion are integrally disposed.

8. An electronic apparatus comprising the physical quantity sensor according to claim 1.
